(19) United States
(12) Patent Application Publication
(10) Pub. No.: US 2026/0235683 A1
(43) Pub. Date: Aug. 13, 2026

(54) METHOD, APPARATUS, AND MACHINE-READABLE PROGRAMMABLE PRODUCT FOR DETERMINING STATE OF CHARGE OF A BATTERY

(71) Applicant: O2Micro Inc., Santa Clara, CA (US)

(72) Inventors: Jing CHE, Wuhan (CN); Heng YANG, Wuhan (CN)

(21) Appl. No.: 19/532,773

(22) Filed: Feb. 6, 2026

(30) Foreign Application Priority Data
Feb. 12, 2025 (CN) 202510158095.8

(51) Int. Cl. G01R 31/367; G01R 31/374; G01R 31/3842; G01R 31/389; G01R 31/396

(52) U.S. Cl. CPC G01R 31/367; G01R 31/374; G01R 31/3842; G01R 31/389; G01R 31/396

(57) ABSTRACT

A method, an apparatus, and a machine-readable program product can determine a state of charge of a battery by: determining a corrected full charge capacity FCC of the battery based on an FCC correction parameter and an initial estimated FCC corresponding to initial battery parameters; determining a present state of charge SOC of the battery based at least in part on the corrected FCC, where the initial estimated FCC is obtained by querying an FCC database based on the initial battery parameters, the FCC database storing battery parameters and respective FCCs, and where the FCC correction parameter is obtained based on a deviation between an estimated SOC and an actual SOC of the battery, and the estimated SOC is obtained by querying an SOC database based on battery parameters including the initial battery parameters, the SOC database storing battery parameters and respective SOC values.

### RELATED APPLICATION

This application claims benefit under 35 U.S.C. § 119(a) to Application No. 202510158095.8, filed with the State Intellectual Property Office of the People's Republic of China on Feb. 12, 2025, which is hereby incorporated by reference in its entirety.

### FIELD

The present disclosure relates to the technical field of new energy, and in particular to battery management technologies. More specifically, the present disclosure relates to methods, apparatus, and machine-readable programmable products for determining a state of charge (SOC) of a battery.

### BACKGROUND

With the widespread use of electronic products, various types of batteries are widely used in the industry. Lithium batteries are particularly valued in various fields due to their high specific energy, light weight, low self-charge rate, and good cycle life. The batteries often require various different charging strategies to be applicable to a wide variety of application scenarios.

For different charging strategies, how to intelligently achieve an accurate and reliable determination of a state of charge of a battery, especially a lithium battery, during a charging process is of great practical significance for improving the charging process, enhancing battery use and utilization efficiency, improving user convenience, and further promoting development of the battery market.

Existing methods for estimating a state of charge (SOC) of a battery mainly include a Coulomb integration method, an open-circuit voltage method, a method that is a combination of the Coulomb integration and open-circuit voltage methods, and a dynamic voltage method.

In the Coulomb integration method, the SOC of a battery is dynamically estimated by accumulating changes in charge level during a charging. This method is simple to calculate, easy to implement, and has a low requirement for a microprocessor. However, the Coulomb integration method requires obtaining an initial SOC value of the battery in advance, and is prone to cumulative errors. As an operating condition of a lithium battery changes, a total rechargeable capacity of the battery changes. In particular, the total rechargeable capacity of the battery decreases significantly at a low temperature (below 0° C.). In combination with the cumulative error of the coulomb integration, it is difficult to accurately estimate a remaining capacity.

In the open-circuit voltage method, an SOC is indirectly inferred by measuring a relationship between an open-circuit voltage (OCV) of a battery and a lithium-ion concentration in the battery. In this method, the target battery is required to rest (neither charging nor discharging) for more than one hour, and the SOC inferred by the open-circuit voltage method may differ significantly from an actual SOC at different temperatures or at different stages of battery life.

With the method combining the Coulomb integration and open-circuit voltage methods, the cumulative error inherent in Coulomb integration is eliminated, but the problem of variation of a total rechargeable capacity of a battery caused by a change in operating condition, such as ambient temperature, is still not solved.

The dynamic voltage method is simple in structure and requires low computing capability of a microprocessor. However, due to a sampling error of battery voltage and a nonlinear relationship between the voltage and the SOC, the accuracy of this method is relatively low. As a result, this method is applicable only to mobile devices seeking a low cost and having a low requirement for accuracy.

### SUMMARY

In view of the importance of SOC estimation during battery charging, the present disclosure provides methods, apparatus, and a machine-readable programmable product for determining a state of charge of a battery. According to this disclosure, the SOC of the battery can be estimated accurately, battery use and utilization efficiency are enhanced, and user experience is improved.

Provided here is a brief summary of the present disclosure, which is intended to provide a basic understanding of aspects of the present disclosure. This summary is not an exhaustive overview of the present disclosure. The summary is not intended to identify key or critical portions of the present disclosure or to delineate the scope of the present disclosure. The purpose is merely to present some concepts in a simplified form, as a prelude to the more detailed description that is presented later.

According to an aspect of the present disclosure, a method for determining a state of charge of a battery is provided. The method includes: determining a corrected full charge capacity (FCC) of the battery based on an FCC correction parameter and an initial estimated FCC corresponding to an initial battery parameter of the battery; and determining a present state of charge (SOC) of the battery based at least in part on the corrected FCC, where the initial estimated FCC is determined by querying an FCC database based on the initial battery parameter, the FCC database storing at least a first set of battery parameters and respective FCCs, and where the FCC correction parameter is determined based on a deviation between an estimated SOC and an actual SOC of the battery, and where the estimated SOC is determined by querying an SOC database based on a second set of battery parameters including the initial battery parameter, the SOC database storing the second set of battery parameters and respective SOC values.

According to an aspect of the present disclosure, an apparatus for determining a state of charge of a battery is provided. The apparatus includes a processing circuit, configured to perform the following steps: determining a corrected FCC of the battery based on an FCC correction parameter and an initial estimated FCC corresponding to an initial battery parameter of the battery; and determining a present SOC of the battery based at least in part on the corrected FCC, where the initial estimated FCC is determined by querying an FCC database based on the initial battery parameter, the FCC database storing at least a first set of battery parameters and respective FCCs, and where the FCC correction parameter is determined based on a deviation between an estimated SOC and an actual SOC of the battery, and the estimated SOC is determined by querying an SOC database based on a second set of battery parameters including the initial battery parameter, the SOC database storing the second set of battery parameters and respective SOC values.

According to other aspects of the present disclosure, machine-readable code and a machine-readable programmable product for implementing the above method are also provided. In addition, a non-transitory computer-readable storage medium recording executable instructions is provided. The executable instructions, when executed by a processor, cause the processor to perform the method or the functions of the apparatus as described above.

With the method, the apparatus, and the machine-readable programmable product according to the embodiments of the present disclosure, in the process of calculating the SOC of the battery, the initial estimated FCC from the FCC database storing the first set of battery parameters and respective FCCs, and the FCC correction parameter determined based on a deviation between the estimated SOC and the actual SOC of the battery are utilized. In this way, the FCC can be corrected appropriately by using the deviation between a historical estimated SOC and an actual SOC, so that the accuracy of SOC determination is improved.

With the embodiments of the present disclosure, the state of charge of the battery can be determined accurately, battery use and utilization efficiency are enhanced, and the user experience is improved.

These and other advantages of the present disclosure become more apparent through the disclosed embodiments described in detail below in conjunction with accompany drawings.

### BRIEF DESCRIPTION OF THE DRAWINGS

For further illustration of the above and other advantages and features of the present disclosure, embodiments of the present disclosure are described in detail hereinafter in conjunction with accompanying drawings. The drawings, together with the detailed description below, are incorporated into and form a part of the specification. Elements having the same function and structure are denoted by same reference signs. Dashed lines in the figures represent optional steps or optional components. The drawings illustrate examples of the present disclosure and should not be construed as a limitation to the scope of the present disclosure. In the drawings:

FIG. 1 illustrates a flowchart of a method for determining a state of charge of a battery according to an embodiment of the present disclosure;

FIG. 2A illustrates a flowchart of a method for determining an initial estimated FCC by querying an FCC database according to an embodiment of the present disclosure;

FIG. 2B illustrates a flowchart of a method for determining an FCC correction parameter by querying an SOC database according to an embodiment of the present disclosure;

FIG. 3 illustrates a flowchart of a method of determining a present SOC based on a corrected FCC according to an embodiment of the present disclosure;

FIG. 4 illustrates a flowchart of a method for determining a state of charge of a battery according to an embodiment of the present disclosure;

FIG. 5 illustrates a flowchart of a method for updating an FCC database according to an embodiment of the present disclosure;

FIG. 6 illustrates a block diagram of an apparatus or system (e.g., a computer system) for determining a state of charge of a battery according to an embodiment of the present disclosure;

FIG. 7A illustrates an example of experimental results and deviations for determining an SOC under a low current condition according to an embodiment of the present disclosure;

FIG. 7B illustrates an example of experimental results and deviations for determining an SOC under a high current condition according to an embodiment of the present disclosure;

FIG. 7C illustrates an example of experimental results and deviations for determining an SOC under a rapid charging condition according to an embodiment of the present disclosure; and

FIG. 8 illustrates an example of a comparison between an SOC value determined according to an embodiment of the present disclosure and an actual SOC of a lithium battery in 19 charge-discharge cycles.

### DETAILED DESCRIPTION

Embodiments of the present disclosure are described below in conjunction with the drawings. For the sake of clarity and conciseness, not all features of an actual embodiment are described in the specification. However, numerous implementation-specific decisions shall or may be made in development of any actual implementations so as to achieve specific objectives of a developer, for example, to comply with system- and business-related constraints, which may vary from one implementation to another. Furthermore, that development work, although it may appear to be complicated and time-consuming, is only a routine task for those skilled in the art benefiting from the present disclosure.

To avoid obscuring the present disclosure due to unnecessary details, only selected apparatus structures and/or processing steps are illustrated in the drawings, and other details less related to the present disclosure are omitted.

Reference will now be made in detail to the various embodiments of the present disclosure, examples of which are illustrated in the accompanying drawings. While described in conjunction with these embodiments, they are not intended to limit the disclosure to these embodiments. On the contrary, the disclosure is intended to cover alternatives, modifications and equivalents, which may be included within the spirit and scope of the disclosure as defined by the appended claims. Furthermore, in the following detailed description of the present disclosure, numerous specific details are set forth in order to provide a thorough understanding of the present disclosure. However, the present disclosure may be practiced without these specific details. In other instances, well-known methods, procedures, components, and circuits have not been described in detail so as not to unnecessarily obscure aspects of the present disclosure.

Some portions of the detailed descriptions that follow are presented in terms of procedures, logic blocks, processing, and other symbolic representations of operations on data bits within a computer memory. These descriptions and representations are the means used by those skilled in the data processing arts to most effectively convey the substance of their work to others skilled in the art. In the present application, a procedure, logic block, process, or the like, is conceived to be a self-consistent sequence of steps or instructions leading to a desired result. The steps are those utilizing physical manipulations of physical quantities. Usually, although not necessarily, these quantities take the form of electrical or magnetic signals capable of being stored, transferred, combined, compared, and otherwise manipulated in a computer system. It has proven convenient at times, principally for reasons of common usage, to refer to these signals as transactions, bits, values, elements, symbols, characters, samples, pixels, or the like.

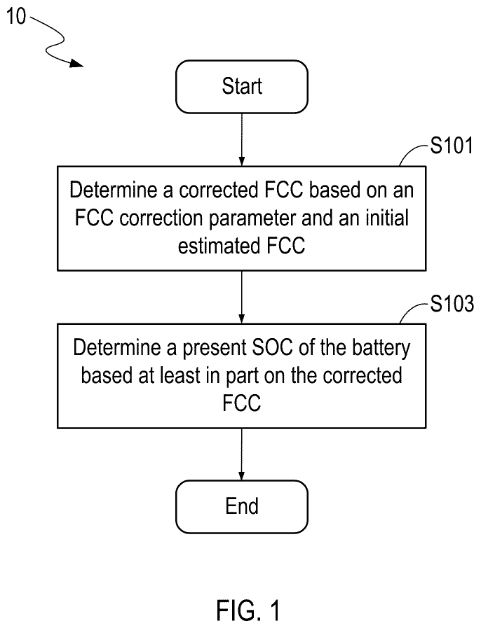

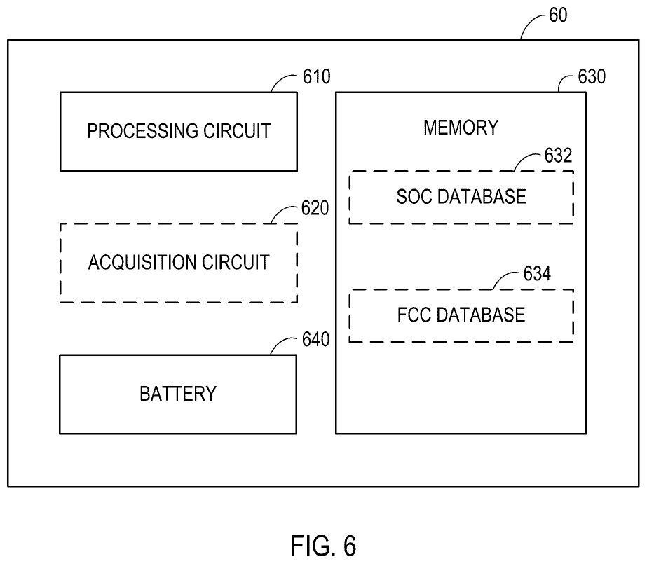

It should be borne in mind, however, that all of these and similar terms are to be associated with the appropriate physical quantities and are merely convenient labels applied to these quantities. Unless specifically stated otherwise as apparent from the following discussions, throughout the present disclosure, discussions utilizing terms such as “calculating,” “obtaining,” “querying,” “storing,” “determining,” “updating,” “measuring,” or the like, may refer to actions and processes of and executed by an apparatus or computer system (e.g., the apparatus or system 60 of FIG. 6) or similar electronic computing device or processor (e.g., the actions and processes of the methods of FIGS. 1, 2A, 2B, 3, 4, and 5). A computer system or similar electronic computing device manipulates and transforms data represented as physical (electronic) quantities within memories, registers or other such information storage, transmission or display devices. In its most basic configuration, a computer system or the like includes at least one processing unit and memory. The computer system may also have additional features and/or functionality, such as the capability for communicating with other devices, the capability to receive user inputs, and the capability to display results.

Embodiments described herein may be discussed in the general context of computer-executable instructions residing on some form of computer-readable storage medium, such as modules, executed by one or more computers, other devices, or circuits. By way of example, and not limitation, computer-readable storage media may comprise non-transitory computer storage media and communication media. Generally, modules may include software, routines, programs, objects, components, data structures, etc., that perform particular tasks or implement particular abstract data types. The functionality of the modules may be combined or distributed as desired in various embodiments. Modules may also be implemented using circuits such as an acquisition circuit or a processing circuit (e.g., a chip or a processor). Moreover, the modules are merely logical modules defined based on specific functions implemented by the modules and are not intended to limit an implementation. For example, a module may be implemented by one or more application-specific integrated circuits, software programs, or a combination thereof.

Computer storage media includes volatile and nonvolatile, removable and non-removable media implemented in any method or technology for storage of information such as computer-readable instructions, data structures, program modules or other data. Computer storage media includes, but is not limited to, random access memory (RAM), read only memory (ROM), electrically erasable programmable ROM (EEPROM), flash memory (e.g., an SSD) or other memory technology, compact disk ROM (CD-ROM), digital versatile disks (DVDs) or other optical storage, magnetic cassettes, magnetic tape, magnetic disk storage or other magnetic storage devices, or any other medium that can be used to store the desired information and that can accessed to retrieve that information.

Communication media may embody computer-executable instructions, data structures, and modules, and includes any information delivery media. By way of example, and not limitation, communication media may include wired media such as a wired network or direct-wired connection, and wireless media such as acoustic, radio frequency (RF), infrared and other wireless media. Combinations of any of the above can also be included within the scope of computer-readable media.

As used herein, a parameter or the like may be the name of a property or metric (e.g., state of charge, full charge capacity, current, temperature, etc.) or the numerical value of that property or metric. A person of ordinary skill in the art will understand how the term is being used based on its context. The term “present” or “current” may be used to refer to the point in time when, for example, a property or metric is measured or determined (e.g., calculated or otherwise obtained).

### Method, Apparatus, and Machine-Readable Programmable Product for Determining State of Charge of a Battery

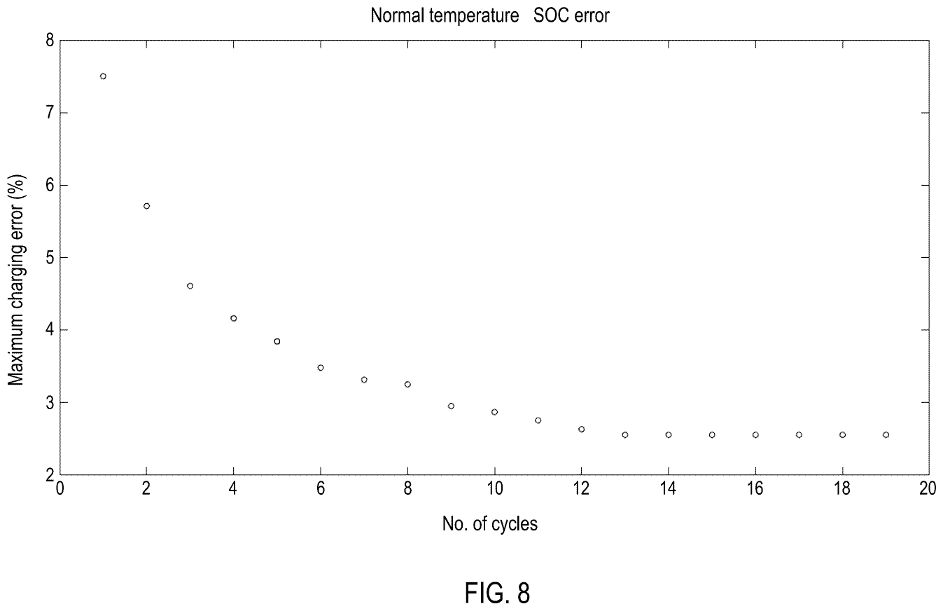

As discussed in the background above, accurate presentation of a state of charge (SOC) of a battery is an important performance indicator in battery-powered electronic devices such as but not limited to mobile phones and palmtop computers. Embodiments according to the presently disclosed invention are integrated into a practical application, namely the accurate and efficient calculation of SOC in real time. More specifically, these embodiments improve the accuracy of the SOC estimation. This improvement provides a dual benefit: it improves device performance by preventing unexpected shutdowns, and it extends battery lifespan by mitigating conditions that accelerate aging, such as deep discharge and overcharging. The ranges of values of the parameters used to calculate SOC, and the various combinations of those parameters and their values, can complicate the calculation of SOC; therefore, accurate, quick, and efficient calculations of SOC is beyond the capability of a human and relies on the use of a computing system or the like (e.g., FIG. 8), particularly considering the time constraints associated with determining SOC in real time.

### Method Embodiments

These embodiments provide methods for determining a state of charge of a battery (e.g., the battery 640 of FIG. 6).

FIG. 1 illustrates a flowchart of a method 10 for determining a state of charge of a battery according to a first embodiment. As shown in FIG. 1, the method 10 includes a step S101 of determining (e.g., reading, accessing, calculating, obtaining, or the like) a corrected full charge capacity (FCC) of the battery based on i) an FCC correction parameter and ii) an initial estimated FCC corresponding to initial battery parameters of the battery; and a step S103 of determining a present state of charge (SOC) of the battery based at least in part on the corrected FCC.

Here, the initial estimated FCC may be determined by querying an FCC database (e.g., the FCC database 634 of FIG. 6) based on the initial battery parameters, the FCC database storing at least battery parameters and values of initial estimated FCCs in association with each other (e.g., the values of FCCs in the FCC database are a function of or are indexed by the battery parameters in the FCC database; a respective FCC is associated with each battery parameter of set of battery parameters). For example, the initial battery parameters used for the query may be prestored battery parameters that are present or instantiated upon the initial activation or first-use cycle of the battery.

In addition, the FCC correction parameter may be determined based on a deviation between an estimated SOC and an actual SOC of the battery. The estimated SOC is determined by querying an SOC database (e.g., the SOC database 632 of FIG. 6) based on a combination of battery parameters including the initial battery parameters, the SOC database storing battery parameters and SOC values in association with each other (e.g., the SOC values in the SOC database are a function of or are indexed by the battery parameters in the SOC database).

In an embodiment, the initial battery parameters may include current and temperature.

As an example, in step S101 of FIG. 1, the corrected FCC may be determined based on the following equation (1):

$$Corrected FCC = Initial estimated FCC * ( 1 + {FCC}_{comp} ) . \qquad Equation ( 1 )$$

In equation (1), the initial estimated FCC is determined using the FCC database, and FCC_{comp} represents the FCC correction parameter, which indicates a capacity deviation that occurs when the battery is not fully discharged or is over-discharged due to temperature changes, battery aging, or other factors. In an embodiment of the present disclosure, the FCC correction parameter is determined based on a deviation between an estimated SOC and an actual SOC of the battery according to the following equation:

$${FCC}_{comp} = ( {SOC}_{actual} - {SOC}_{estimated} ) * Initial estimated FCC . \qquad Equation ( 2 )$$

In equation (2), the estimated SOC is determined by querying the SOC database based on the combination of battery parameters including the initial battery parameters. The actual SOC may be measured, for example, using a cycler.

As an example, in step S103, the present state of charge (SOC) of the battery may be determined based on the following equation (3):

$$Present SOC = RCA / Corrected FCC . \qquad Equation ( 3 )$$

In equation (3), RCA represents a present charge level of the battery (that is, a present remaining capacity), which may be determined, for example, based on a previous charge level of the battery and a change in the charge level of the battery (e.g., charged capacity). The corrected FCC is the calculation result of equation (1).

Although not shown in FIG. 1, a process for determining (e.g., measuring, or reading from computer system memory) the required battery parameters (present battery parameters and/or battery parameters during an initial charging stage) is, in embodiments, performed between or before step S101 and step S103. The battery parameters may include, but are not limited to, battery voltage (a voltage across the battery), battery current (a current flowing through the battery), battery temperature, battery state, SOC, coulomb capacity, cutoff current, charging limit voltage, rated capacity, and/or health value.

In this way, the SOC may be calculated using the FCC that is corrected based on a deviation between the estimated SOC and the actual SOC, so that the accuracy of determining the SOC is improved.

Details of the FCC database and methods performed using the FCC database are described below.

In embodiments, the FCC database may be two-dimensional, but is not limited thereto. For example, an FCC database may include a current dimension and a temperature dimension, with the FCC data at each temperature and current point including at least an initial estimated FCC.

As an example, the FCC database may describe an estimated FCC under a condition of a specific value temp of temperature T and a specific value curr of current I. In this example, the FCC database includes two parameters or data space dimensions: temperature and current. The FCC database also includes at least an estimated FCC associated with (e.g., a respective value corresponding to or indexed by) each temperature and current pair (each combination of [temp, current]) in the FCC database. Alternatively (e.g., in a three-dimensional database), data in the FCC database may further include an initial capacity of the battery, which at the initial moment is equal to a product of a previously measured battery health value and a battery rated capacity. The initial moment here may be considered as a time instant when the SOC at the start of charging and the SOC at the end of charging are both zero in the charging data, or the time instant when data during the charging process has not yet been updated.

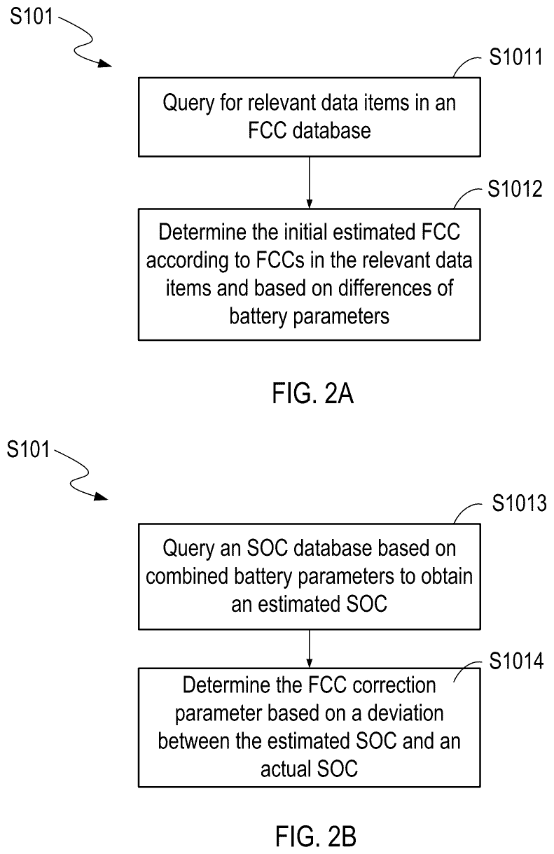

As shown in FIG. 2A, step S101 of FIG. 1 also includes: step S1011, querying for relevant data items in the FCC database based on the initial battery parameters; and step S1012, determining the initial estimated FCC according to FCCs in the relevant data items and based on differences between battery parameters in the relevant data items and the initial battery parameters.

As an example, in step S1011, the initial estimated FCC is obtained from the FCC database by querying for relevant data items in the FCC database with a battery current and temperature (curr, temp) at the initial charging stage.

For example, a query to the FCC database may be implemented with a two-dimensional linear interpolation algorithm. An example execution flow of the two-dimensional linear interpolation algorithm is as follows.

First, based on measured battery parameters (I=curr, T=temp), current points curr₀ and curr₁ closest to the current curr, and temperature points temp₀ and temp₁ closest to the temperature T, are found in the FCC database. In a particular implementation, in a case where the current curr is greater than or equal to the maximum value (e.g., 10 A) of the current points in the FCC database, or less than the minimum value (e.g., 2 A) of the current points in the FCC database, then curr₀ and curr₁ are set to those maximum and minimum currents, respectively; and in a case where the temperature temp is greater than or equal to the maximum value (e.g., 65° C.) of the temperature points in the FCC database, or less than the minimum value (e.g., 5° C.) of the temperature points in the FCC database, then temp₀ and temp₁ are set to those maximum and minimum temperatures, respectively. Those skilled in the art will understand that the specific values of the temperature and current mentioned above are for illustrative purposes only, and those skilled in the art may set the maximums and minimums to those values or to different values.

After the above is performed, an estimated FCC fcc_est_{curr0,temp0} corresponding to the current curr₀ and temperature point temp₀, an estimated FCC fcc_est_{curr0,temp1} corresponding to the current curr₀ and temperature point temp₁, an estimated FCC fcc_est_{curr1,temp0} corresponding to the current curr₁ and temperature point temp₀, and an estimated FCC fcc_est_{curr1,temp1} corresponding to the current curr₁, and temperature point temp₁, are searched for in the FCC database.

Using the above values, a temperature weight and a current weight are calculated for each data point, where temperature weights corresponding to temp₀ and temp₁ are calculated as:

$${temp\_weight}_{0} = \frac{{temp}_{1} - temp}{{temp}_{1 -} {temp}_{0}} * Coeff ;$$

$${temp\_weight}_{1} = Coeff - {temp\_weight}_{0} ;$$

and
current weights corresponding to curr₀ and curr₁ are calculated as:

$${curr\_weight}_{0} = \frac{{curr}_{1} - curr}{{curr}_{1 -} {curr}_{0}} * Coeff ;$$

$${curr\_weight}_{1} = Coeff - {curr\_weight}_{0} .$$

Here, Coeff in the above equations is a coefficient applied to facilitate calculation of the weights. In an implementation, Coeff is equal to 1000; however, those skilled in the art will understand that this coefficient may be set to another value based on a specific application need.

Subsequently, the temperature weights, current weights, and estimated FCCs at corresponding temperature and current values determined as just described are substituted into the following equation to determine an initial estimated FCC corresponding to (curr, temp):

$$Initial estimated FCC = \frac{1}{{( Coeff )}^{2}} {\sum }_{i = 0}^{1} {\sum }_{j = 0}^{1} {temp\_weight}_{i} * {curr\_weight}_{j} * {fcc\_est}_{{temp}_{i} , {curr}_{j}} .$$

Here, the coefficient

$$\frac{1}{{( Coeff )}^{2}}$$

is for ease of calculation, and may be set to a value based on a specific application need.

In embodiments, for the battery parameter for querying the FCC database, curr may be selected as the maximum current value currₘₐₓ during the charging process, and temp may be selected as an average temperature value temp_{avg} during the charging process, but the present disclosure is not limited thereto.

Details of the SOC database and an embodiment of a process performed using the SOC database are described below.

The SOC database may be referred to as an RC table. In an embodiment of the method 10 (FIG. 1) for determining a state of charge of a battery, the SOC database may be three-dimensional, but is not limited thereto. As an example, the SOC database may include a voltage dimension, a current dimension, and a temperature dimension (that is, the battery parameters involve three dimensions), and the battery capacity at each voltage point, temperature point, and current point includes an SOC value of the battery at the corresponding voltage, temperature, and current.

In the three-dimension embodiment, the SOC database includes an SOC value under a condition of a specific voltage V, a specific temperature T, and a specific current I. Data in the corresponding data space includes at least an SOC value of the battery in the abovementioned condition.

As mentioned above, in step S101 (FIG. 1), the FCC deviation that occurs when the battery (e.g., a lithium battery) is not fully discharged, or is over-discharged due to temperature changes, battery aging or other factors, is corrected in step S101 using the FCC correction parameter. In an embodiment, as shown in FIG. 2B, the step of determining the FCC correction parameter in step S101 also includes: step S1016, obtaining an estimated SOC by querying the SOC database based on a combination of battery parameters; and step S1017, determining an FCC correction coefficient based on a deviation between the estimated SOC and an actual SOC.

As an example, the estimated SOC may be obtained by querying the SOC database based on a combination of battery parameters including the initial battery parameters, the SOC database storing battery parameters and SOC values in association with each other (e.g., the estimated SOC values are indexed by the combinations of battery parameters). Here, a combination of battery parameters may include a first equivalent voltage and a second equivalent voltage of the battery. The first equivalent voltage represents a sum of an idle voltage and a charging impedance voltage of the battery, and the second equivalent voltage represents a sum of a charging cutoff voltage and a charging impedance voltage of the battery. In an implementation, querying the SOC database based on a combination of battery parameters includes: querying the SOC database based on the first equivalent voltage of the battery, an initial current, and an initial temperature, to obtain a first SOC; querying the SOC database based on the second equivalent voltage, the initial current, and the initial temperature of the battery, to obtain a second SOC; and determining the estimated SOC as a difference between the first SOC and the second SOC, where the first equivalent voltage is a sum of the idle voltage and the charging impedance voltage of the battery, and the second equivalent voltage is a sum of the charging cutoff voltage and the charging impedance voltage of the battery.

As an example, a specific process of querying the SOC database to determine the first SOC and the second SOC, and then determining the estimated SOC, is performed as follows.

The SOC database is queried based on a combination of battery parameters. The combination of battery parameters include at least a current, a temperature, a charging impedance voltage, an idle voltage idle_volt representing a voltage when the battery has no load, and a discharging cutoff voltage eod_volt of the battery. In embodiments, the SOC database is an RC table with three data dimensions: voltage (volt), current (curr), and temperature (temp). The querying may be performed through a three-dimensional linear interpolation method.

Using the query for the SOC used to determine the estimated SOC as an example, the first SOC (SOC_{now}) and the second SOC (SOC_{end}) may be determined through an operation of querying the SOC database as expressed by the following equations:

$${SOC}_{now} = RC ( idle\_volt + curr * ( sysim + chgir ) , curr , temp ) ; and$$

$${SOC}_{end} = RC ( eod\_volt + curr * ( sysim + chgir ) , curr , temp ) .$$

In these equations, idle_volt represents an idle voltage, eod_volt represents a cutoff voltage, curr represents a current used for the querying, temp represents a temperature used for the querying, sysim represents a line resistance indicating a line impedance, and chgir represents a battery internal resistance.

With the above RC table query operation, SOC_{now} (corresponding to the idle voltage idle_volt when the battery has no load) and SOC_{end} (corresponding to the discharging cutoff voltage eod_volt of the battery when charging stops) can be determined. Based on this, the estimated SOC can be determined, that is, estimated as: SOC=SOC_{now}−SOC_{end}.

Accordingly, the FCC correction parameter fcc_{comp} used in equation (2) above can be determined, where the estimated FCC is determined as described above, and the actual SOC may be measured, for example, with a cycler. Therefore, the above process for determining the estimated SOC prevents the estimated battery SOC from being artificially high or low due to battery aging or temperature changes.

In embodiments, the battery temperature is sampled in real time throughout the charging process, and the charging battery temperature used to query the SOC database is calculated based on a single present sampled value of the battery temperature. The present disclosure does not impose any particular restrictions on the “single present sampled value” of the battery temperature or the method of calculating the “charging battery temperature” based thereon. For example, the “single present sampled value” of the battery temperature may be a sampled value taken at charging cutoff, and that sampled value may be used as the “charging battery temperature.” As other examples, the sampled value of the battery temperature may be selected from other sampled values of the battery temperature during the charging process or from statistics of these sampled values, which are not described further in detail here.

Based on the estimated FCC and the FCC correction parameter fcc_{comp} determined from the above steps, the corrected FCC can be determined (step S101 of FIG. 1 and equation (1)).

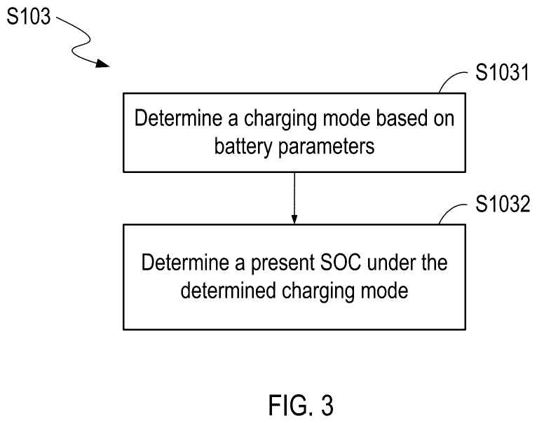

As mentioned above, in step S103 (FIG. 1), a present state of charge SOC of the battery is determined based at least in part on the corrected FCC. Next, an embodiment of determining a present SOC of the battery based at least in part on the corrected FCC is described further with reference to FIG. 3. In an implementation, as shown in FIG. 3, step S103 of FIG. 1 also includes: step S1031, determining a charging mode of the battery based on present battery parameters; and step S1032, determining the present SOC for the determined battery charging mode.

In embodiments, battery charging modes may include a constant current charging mode and a constant voltage charging mode.

As an example, the battery is charging in the constant voltage charging mode in a case where the battery meets a constraint of constant voltage charging, and otherwise the battery is charging in the constant current charging mode. Constraints associated with the constant voltage charging mode include, for example, an average voltage being greater than or equal to a charging limit voltage, an average current being greater than zero, a long-term average current (e.g., an average current over a period of 45 seconds) being greater than a short-term average current (e.g., an average current over a period of 15 seconds), and a voltage fluctuation being less than a certain fraction (e.g., less than 1/100) of an average voltage.

In embodiments, in a case where the determined charging mode is the constant current charging mode, the present SOC is determined based on a present charge level of the battery and the corrected FCC.

As an example, the present charge level, e.g., the residual capacity (RCA), of the battery is updated using the charged capacity deltauah of the battery. The present SOC is then determined using the updated RCA and the corrected FCC determined in step S101 (FIG. 1). For example, the present SOC may be determined through the following two equations:

$$RCA = RCA + deltauah , SOC = \frac{RCA}{corrected FCC} * Const 1.$$

The constant Const1 is applied to facilitate calculations by eliminating the decimal point of SOC. In an embodiment, Const1 is equal to 10,000. Those skilled in the art will understand that the value of Const1 may not be used or a different value may be used depending on the application.

In embodiments, in a case where the determined charging mode is the constant voltage charging mode, the present SOC is determined based on a relationship between a present charging current of the battery and a present reference current, where the present reference current is determined based at least on a previous SOC, a previous charging current, and a charging cutoff current of the battery.

In embodiments, determining the present SOC based on a relationship between the present charging current and the present reference current includes: determining the present SOC as a sum of a previous SOC and a predetermined SOC increment in a case where a difference between the present charging current and the present reference current is equal to zero. Here, “equal to” includes the case of “substantially equal to,” meaning that the present charging current or statistics associated therewith may differ from the reference current slightly due to factors such as measurement resolution and measurement error, but the difference between the present charging current and the reference current is within an acceptable predetermined range. In embodiments, the present SOC is determined as a sum of a previous SOC and a predetermined SOC increment in each case where a difference between the present charging current and the present reference current is equal to, or substantially equal to, zero. For example, in the constant voltage charging mode, as the present charging current changes, the SOC may be updated whenever the difference between the present charging current and the present reference current is equal to, or substantially equal to, zero.

In embodiments, the difference between the present charging current and the present reference current is determined based on a sum of i) a first difference between the present charging current and the previous charging current, and ii) a second difference between a) a previous charging current adjusted based on the previous SOC and a predetermined adjustment factor and b) the charging cutoff current. Alternatively, the difference between the present charging current and the present reference current may be determined based on a difference between the first difference and the second difference, where here the second difference is for measuring whether the first difference (e.g., a change in the charging current) meets a condition for increasing the SOC. The sum or difference of the first difference and the second difference may be applied as described or in reverse order, the only difference being that in the latter case the adjustment factor will be either positive or negative.

As an example, an average charging current over a certain period of time (e.g., 15 seconds) may be selected as a representation of the previous charging current, in which case the present reference current may be expressed as:

$${ref}_{curr} = {curr}_{avg} - \frac{( {curr}_{avg} - eoc ) * ratio}{Const 1 - SOC} .$$

Here, eoc represents a cutoff current, SOC represents the previous state of charge, and ratio (e.g., the adjustment factor), represents an empirical value that is adjustable based on an actual need. A step size, or a frequency, of the present charging current “catching up” with the present reference current may be controlled by adjusting the value of the ratio, e.g., the present charging current can be made to be equal to the present reference current by adjusting the ratio.

From the above equation, the difference between the present charging current and the present reference current is a sum of (present curr_{avg}−previous curr_{avg}) and

$$\frac{( previous {curr}_{avg} - eoc ) * ratio}{Const 1 - SOC} .$$

In a case where the difference between the present charging current and the present reference current is zero (or substantially equal to zero, as defined above), the present SOC is determined to be a sum of the previous SOC and the predetermined SOC increment.

As an example, the ratio may be set to an integer value, but the present disclosure is not so limited. In an embodiment, a single ratio is used during the charging process. Alternatively, multiple different ratios may be used throughout the charging process, so as to flexibly adjust the step size while the present current is “catching up” with the reference current if needed for any reason.

As an example, only one fixed SOC increment, such as 10 or 100, may be selected in the constant voltage charging mode throughout the charging process. Alternatively, multiple different SOC increments may be selected throughout the charging process, so as to flexibly adjust a smoothness of change in the determined SOC if needed for any reason.

An example of a method for determining the SOC based on a “catching up” process during a constant voltage charging process (that is, the battery is in the constant voltage charging mode), in which multiple different ratios and one fixed SOC increment are applied, is presented as follows. The method in this example includes a first step, a second step, and a third step.

In the first step, assuming that Const1 is 10,000, the eoc is 250 mA, the predetermined SOC increment is 10 (e.g., 10/10000), the average current at the start of the “catch-up” operation is 801 mA, the SOC is 9716 (i.e., 9716/10000), and the ratio1 is 10, then a first reference current is obtained based on the above data as:

$${ref}_{curr 1} = {curr}_{avg 0} - \frac{( {curr}_{avg 0} - eoc )}{\frac{10000 - {SOC}_{0}}{ratio 1}} = 781.6 mA .$$

In the second step, because the charging current gradually decreases as the SOC increases during constant voltage charging, the SOC is updated to include the predetermined increment of 10 when the average current drops to the first reference current 781.6 mA. At this point, the SOC is 9726. Furthermore, to catch up more frequently with a smaller interval, ratio2 is set to five (5). Therefore, a second reference current is:

$${ref}_{curr 2} = {curr}_{avg 1} - \frac{( {curr}_{avg 1} - eoc )}{\frac{10000 - {SOC}_{1}}{ratio 2}} = 771.9 mA .$$

In the third step, when the average current drops to the second reference current 771.9 mA, the SOC is updated to include the predetermined increment. At this point, the SOC is 9736, and the ratio is still set to ratio2=5. Therefore, a third reference current is:

$${ref}_{curr 3} = {curr}_{avg 2} - \frac{( {curr}_{avg 2} - eoc )}{\frac{10000 - {SOC}_{0}}{ratio 2}} = 762. mA .$$

This process continues until the average current (e.g., an above-mentioned present charging current) is equal to the charging cutoff current (e.g., an above-mentioned present reference current). Those skilled in the art may set an appropriate mechanism to stop the “catching up” process. For example, the “catching up” process is stopped when a measured present charging current satisfies a constraint, e.g., is less than or equal to a set value (which is less than the charging cutoff current).

The above example implementation for determining the SOC based on the “catching up” method between the charging current and the reference current is for illustrative purposes only. Those skilled in the art may flexibly adjust values of the ratio and the SOC increment if needed for any reason, so that a single ratio value may be used throughout the entire charging process, or multiple different ratio values may be used as the charging process proceeds. Similarly, a single SOC increment may be used throughout the entire charging process, or multiple different SOC increments may be used as the charging process proceeds. The above-mentioned “catching up” method for determining the SOC can effectively improve the accuracy and/or timeliness in situations where SOC updates are inaccurate or untimely during battery charging, especially in cases where the charging current is small.

The above steps S1031 and S1032 (FIG. 3) are not limited to being executed only once, but may be repeated any number of times according to a determination made in real time and based on whether the battery meets any of the aforementioned constraints associated with the constant voltage charging mode. In other words, during a charging process, step S1031 may be executed multiple times if a battery parameter (measured in real time and/or statistically derived from real-time measurements) satisfies a constraint that is used to determine whether the battery charging process is in the constant current charging mode or a constant voltage charging mode (as previously described herein). After each determination of the charging mode, the SOC is updated based on that mode until the next determination.

In embodiments, a charging tail capacity chg_tail_cc during the battery charging process is defined. The charging tail capacity is initially expressed as chg_tail_cc=ratioe*facc, where ratioe represents an empirical value and facc represents a rated capacity of the battery. Whenever the battery charging process enters a constant voltage charging state, the charging tail capacity is updated to chg_tail_cc=chg_tail_cc−deltauah using the charged capacity deltauah of the battery until the charging tail capacity chg_tail_cc is updated to be less than or equal to zero, and then the present SOC is determined as a sum of the previous SOC and the predetermined SOC increment.

Those skilled in the art will readily understand that, for the above steps, a cutoff voltage may be employed for constraint in a manner similar to employing the cutoff current as a constraint as described above. Therefore, the above steps employ the cutoff current and/or cutoff voltage to determine whether the battery is fully charged, which can effectively prevent overcharging or undercharging of the battery. The SOC of the battery can be accurately estimated throughout the entire charging process without changing abruptly, so that the battery life is extended.

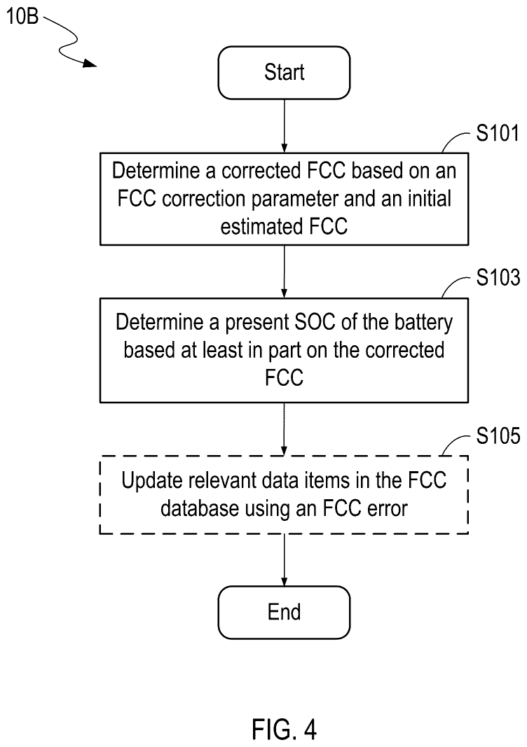

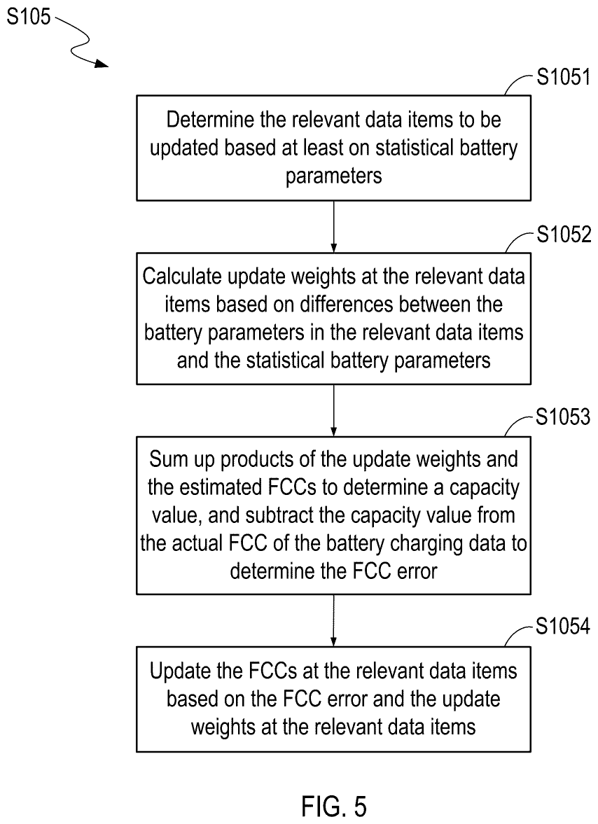

Other embodiments involving methods of updating of the FCC database are described with reference to FIG. 4 and FIG. 5. Those skilled in the art will understand that those embodiments can also be used to acquire data to construct and populate the FCC database.

As shown in FIG. 4, according to an embodiment, a method 10B for determining a state of charge of a battery includes: optional step S105, updating relevant data items in the FCC database using an FCC error when a preset update condition is met, where the FCC error is a calculated deviation between a present estimated FCC and an actual FCC, and where the present estimated FCC is obtained by querying the FCC database based on statistical battery parameters (which may be also referred to as statistical values of battery parameters).

As an example, the preset update condition may be that the battery's temperature change does not exceed a predetermined range during the charging process.

In embodiments, update weights associated with the data items relevant to the battery temperature are calculated based on differences for multiple statistical battery parameters. As an example, the statistical battery parameters may include at least a maximum current currₘₐₓ and an average temperature temp_{avg}.

As an example, updating the FCC database may include: determining the relevant data items to be updated in the FCC database based at least on the statistical battery parameters.

As an example, updating the relevant data items in the FCC database may include: calculating update weights for the relevant data items based on differences between battery parameters in the relevant data items and the statistical battery parameters; and updating FCCs at the relevant data items in the FCC database based on the FCC error and the update weights for the relevant data items.

In embodiments, the actual FCC is a sum of: a cumulative charging capacity during a charging process for the battery, a remaining capacity before charging, and a capacity correction value, where the capacity correction value is determined based on a deviation between an actual SOC at charging cutoff and an estimated SOC, where the estimated SOC is determined by querying the SOC database based on battery parameters including a charging cutoff current.

An example of updating the FCC database is described with reference to FIG. 5. Specifically, as shown in FIG. 5, as an example of step S105 in FIG. 4, the update includes: step S1051, determining the relevant data items to be updated based at least on statistical battery parameters; step S1052, calculating respective update weights for the relevant data items based on differences between the battery parameters in the relevant data items and the statistical battery parameters, where the update weights may include update weights respectively corresponding to each type of battery parameter; step S1053, summing up products of the update weights and the estimated FCCs at the relevant data items to determine a capacity value, and subtracting the accumulated capacity value from the actual FCC of the battery charging data to determine the FCC error; and step S1054, updating the FCCs associated with the relevant data items in the FCC database based on the FCC error and the update weights at the relevant data items.

In step S1051, the relevant data items to be updated may be determined (identified, selected) based on the statistical battery parameters. The statistical battery parameters may include, for example, a maximum current currₘₐₓ and an average temperature temp_{avg}. As an example, the temperature points temp₀ and temp₁ closest to an average temperature temp_{avg}, and the current points curr₀ and curr₁ closest to a maximum current currₘₐₓ, may be searched for in the FCC database, so that two related data items adjacent to the average temperature and two related data items adjacent to the maximum current in the database are determined. The above method for determining the relevant data items is merely an example. Those skilled in the art will clearly understand that other methods for determining the relevant data items to be updated based on the statistical battery parameters are possible.

In step S1052, for each relevant data item, the update weights corresponding to respective battery parameters may be calculated; namely, a temperature weight and a current weight may be calculated. Equations for the temperature weight and the current weight are as follows:

$${temp\_weight}_{0} = \frac{{temp}_{1} - {temp}_{aver}}{{temp}_{1 -} {temp}_{0}} * Const 2 ;$$

$${temp\_weight}_{1} = Const 2 - {temp}_{{weight}_{0}} ;$$

$${curr\_weight}_{0} = \frac{{curr}_{1} - {curr}_{max}}{{curr}_{1 -} {curr}_{0}} * Const 2 ; and$$

$${curr\_weight}_{1} = Const 2 - {curr\_weight}_{0.}$$

In these equations, the value of Const2 is set to reduce the number of decimal places in the weight to facilitate calculations. For example, Const2 may be equal to 1000. Those skilled in the art will understand that Const2 may set to another value accordingly in connection with the next step and/or other steps.

In an example implementation, in a case where an average temperature temp_{avg} is greater than the maximum value (e.g., 65° C.) or less than the minimum value (e.g., 5° C.) of the temperature points in the FCC database, then temp₀ and temp₁ are set to the maximum and minimum temperature values (e.g., 65° C. and 5° C.), respectively; in a case where the maximum current currₘₐₓ is greater than the maximum value (e.g., 10 A) or less than the minimum current (e.g., 2 A) of the current points in the FCC database, then curr₀ and curr₁ are set to the maximum and minimum current values (e.g., 10 A and 2 A), respectively; in a case where temp₀=temp₁, then temp_weight₀=temp_{weight}_{₁} (e.g., 500); and in a case where curr₀=curr₁, then curr_weight₀=curr_{weight}_{₁} (e.g., 500).

In step S1053, as expressed in the following equation, the temperature weights, current weights, and estimated FCCs from the FCC database of the adjacent related data items are multiplied and summed to determine an accumulated capacity value, and the accumulated capacity value is then subtracted from the estimated charged capacity from the battery charging data to determine a capacity error fccₑᵣᵣₒᵣ using the following equation:

$$fcc\_error = {fcc\_est}_{c} - \frac{1}{( Const 2 )} {\sum }_{i = 0}^{1} {\sum }_{j = 0}^{1} {temp\_weight}_{i} * {curr\_weight}_{j} * {fcc\_est}_{{temp}_{i} , {curr}_{j} .}$$

Here, the estimated charged capacity fcc_est_{c} from the battery charging data may be considered to be an “actual FCC,” which is a sum of a cumulative charging capacity during a charging process for the battery, a remaining capacity before charging, and a capacity correction value. The capacity correction value is determined based on a deviation between an actual SOC at charging cutoff and an estimated SOC determined by querying the SOC database based on a combination of battery parameters including a charging cutoff current. The values of i and j in the above equation may be 0 or 1. The following step S1054 is not performed and the FCC database update is terminated in a case where fcc_error≤0.

In step S1054, FCCs for the relevant data items in the FCC database are updated based on the FCC error and the update weights for these relevant data items determined through the above steps.

As an example, the FCC is updated based on the following equation:

$${fcc\_est}_{{temp}_{i} , {curr}_{j}} = {fcc\_est}_{{temp}_{i} , {curr}_{j}} + \frac{1}{{( Const 2 )}^{2}} * {fcc}_{error} * {temp}_{{weight}_{i}} * {curr}_{{weight}_{j}} .$$

In embodiments, the relevant data items to be updated in the FCC database are determined based at least on the battery parameters used in the calculation of the SOC (the battery parameters used for calculating the SOC).

In addition, as mentioned above, those skilled in the art will understand that the embodiments of the method used to update the FCC database can also be used to acquire data to construct and populate the FCC database.

In embodiments, the method 10B (FIG. 5) may further include determining whether full charge is reached based on the SOC determined in the above step. Taking the SOC limited to an integer range from 1 to 10,000 as an example, in a case of SOC<9900, only the time identifier is updated to a present time value. In a case where the battery SOC remains unchanged for a duration greater than a full charge timeout threshold (e.g., 30 seconds), the battery SOC is updated to 10,000, the residual capacity RCA is updated to the corrected FCC, and the state value is updated to the full charge state.

### <Apparatus/System Embodiments>

The following embodiments provide an apparatus or system (e.g., computer system) for determining a state of charge of a battery.

FIG. 6 illustrates a block diagram of functional modules of an apparatus or system (e.g., computer system) 60 for determining a state of charge of a battery according to the second embodiment. As shown in the embodiment of FIG. 6, the apparatus 60 includes a processing circuit 610 and memory 630. In that embodiment, the apparatus 60 also includes a battery 640. However, the battery 640 may instead be external to the other components of the apparatus 60, in which case it can be connected to the apparatus 60 and also may be detached from apparatus 60. In an embodiment, the memory 630 includes an SOC database 632 and an FCC database 634. In an embodiment, the apparatus 60 includes a display window (not shown) for displaying the SOC of the battery 640 and optionally displaying other information about the charging process or the battery.

As shown in FIG. 6, the apparatus or system (computer system) 60 includes a processing circuit 610, configured to determine a corrected full charge capacity FCC of the battery 640 based on an FCC correction parameter and an initial estimated FCC corresponding to initial battery parameters of the battery. The apparatus 60 is also configured to determine a present state of charge SOC of the battery 640 based at least in part on the corrected FCC, where the initial estimated FCC is obtained by querying the FCC database 634 based on the initial battery parameters. The FCC database 634 stores at least battery parameters and respective FCCs, where the FCC correction parameter is determined based on a deviation between an estimated SOC and an actual SOC of the battery 640, and the estimated SOC is obtained by querying the SOC database 632 based on a combination of battery parameters including the initial battery parameters. The SOC database 632 stores battery parameters and respective SOC values. In embodiments, the apparatus 60 further includes an acquisition circuit 620 for acquiring parameters required for processes performed by the processing circuit 610. In embodiments, the acquisition circuit 620 may include a sensor for measuring the battery parameters.

In the above descriptions of the methods for determining a state of charge of a battery, the processing and functions implemented by functional modules of the apparatus 60 for determining a state of charge of a battery have also been disclosed. In summary, each method step and associated processing described above with reference to FIG. 1 to FIG. 5 may be implemented via the processing circuit 610 of FIG. 6 alone or in combination with the acquisition circuit 620. The acquisition circuit 620 is configured to acquire various battery parameters, and the processing circuit 610 is configured to perform various processing, calculation and control. Therefore, a summary of functions of the processing circuits is provided below without repeating some of the details discussed above.

The processing circuit 610 may be implemented as, for example, a chip, a processor, various microcontrollers, or the like, and may be implemented by one or more application-specific integrated circuits and/or corresponding software programs. The acquisition circuit 620 may have at least one sensor to measure and acquire a state parameter of the battery 640 (battery parameter) through the at least one sensor, for example. As mentioned above, battery parameters may include, for example, at least one of a battery voltage, a battery current, and a temperature, but are not limited thereto. For example, the battery parameters may include a (charging) capacity. The temperature may be measured, for example, using a temperature sensor. The battery current may be measured, for example, using a current sensing circuit. The battery voltage may be measured, for example, using a voltage sensing circuit. The capacity may be measured with a coulomb meter.

In an example, the initial battery parameters include at least a current and a temperature.

In an example, the processing circuit 610 may be further configured to: query for relevant data items in the FCC database 634 based on the initial battery parameters; and determine the initial estimated FCC according to FCCs in the relevant data items and based on differences between battery parameters in the relevant data items and the initial battery parameters.

In an example, the processing circuit 610 may be further configured to: query the SOC database based on a first equivalent voltage of the battery, an initial current, and an initial temperature, to obtain a first SOC; query the SOC database 632 based on a second equivalent voltage, the initial current, and the initial temperature of the battery, to determine a second SOC; and determine the estimated SOC as a difference between the first SOC and the second SOC, where the first equivalent voltage is a sum of an idle voltage and a charging impedance voltage of the battery, and the second equivalent voltage is a sum of a charging cutoff voltage and the charging impedance voltage of the battery.

In an example, the processing circuit 610 may be further configured to: determine a charging mode of the battery 640 based on the present battery parameters; and determine the present SOC depending on the determined charging mode.

In an example, the processing circuit 610 may be further configured to: determine the present SOC based on a present charge level of the battery 640 and the corrected FCC, in a case where the determined charging mode is constant current charging.

In an example, the processing circuit 610 may be further configured to: in a case where the determined charging mode is constant voltage charging, determine the present SOC based on a relationship between a present charging current of the battery and a present reference current, where the present reference current is determined based at least on a previous SOC, a previous charging current and a charging cutoff current of the battery.

In an example, the processing circuit 610 may be further configured to: determine the present SOC as a sum of a previous SOC and a predetermined SOC increment in a case where a difference between the present charging current and the present reference current is zero.

In an example, the processing circuit 610 may be further configured to: determine the difference based on a sum of i) a first difference between the present charging current and the previous charging current and ii) a second difference between the previous charging current adjusted based on the previous SOC and a predetermined adjustment factor and the charging cutoff current.

In an example, the processing circuit 610 may be further configured to: when a preset update condition is met, update relevant data items in the FCC database 634 using an FCC error, where the FCC error is a calculation deviation between a present estimated FCC and an actual FCC, the present estimated FCC being obtained by querying the FCC database based on statistical battery parameters.

In an example, the processing circuit 610 may be further configured to: determine the relevant data items to be updated in the FCC database 634 based at least on the statistical battery parameters.

In an example, the processing circuit 610 may be further configured to: calculate update weights for the relevant data items based on differences between battery parameters in the relevant data items and the statistical battery parameters; and update FCCs at the relevant data items in the FCC database 634 based on the FCC error and the update weights for the relevant data items.

In an example, the processing circuit 610 may be further configured to: calculate the update weights at the relevant data items based on differences for multiple statistical battery parameters.

In embodiments, the multiple statistical battery parameters include at least a maximum current and an average temperature.

In embodiments, the actual FCC is a sum of a cumulative charging capacity during a charging process for the battery, a remaining capacity before charging, and a capacity correction value, where the capacity correction value is obtained based on a deviation between an actual SOC at charging cutoff and an estimated SOC obtained by querying the SOC database based on a combination of battery parameters including a charging cutoff current.

### <Effects>

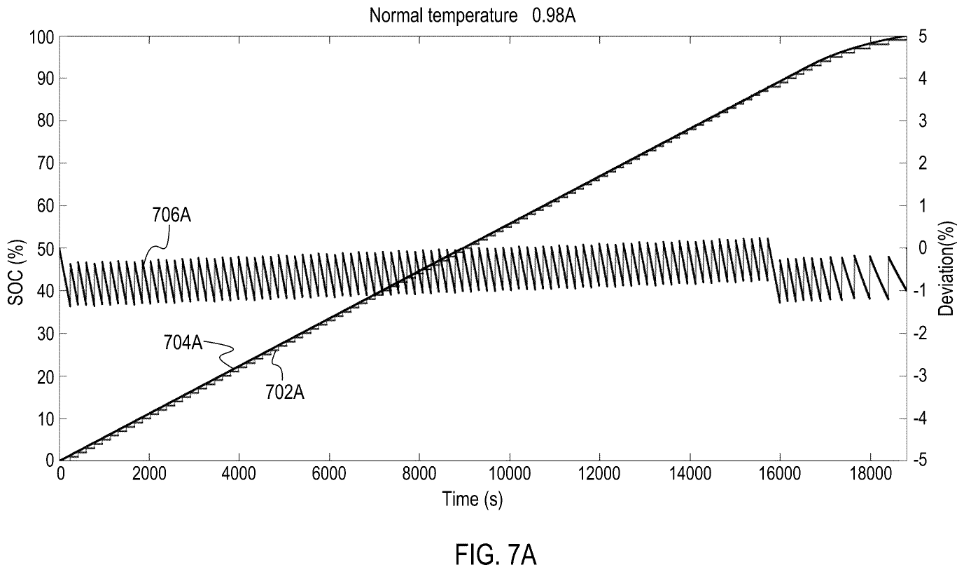

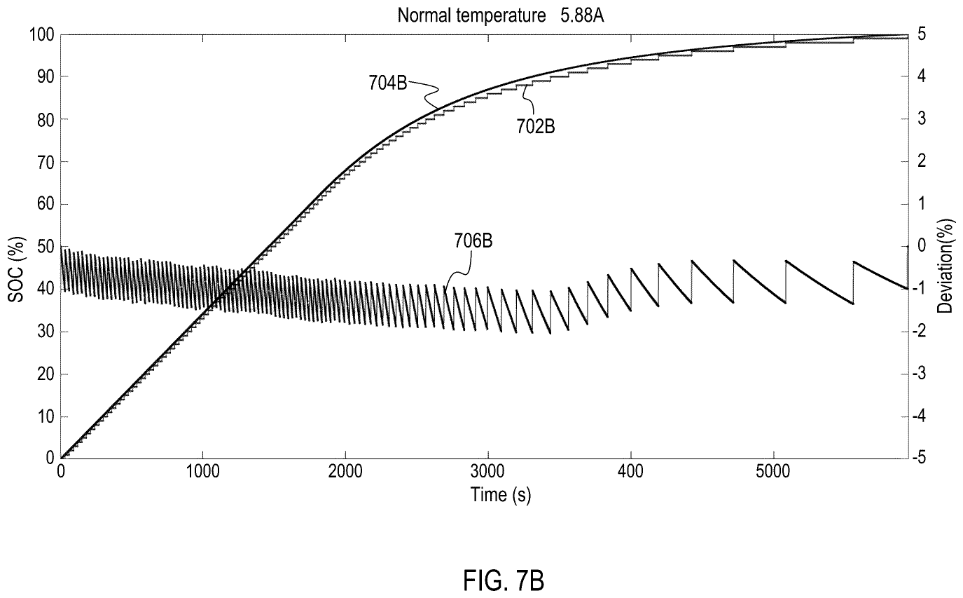

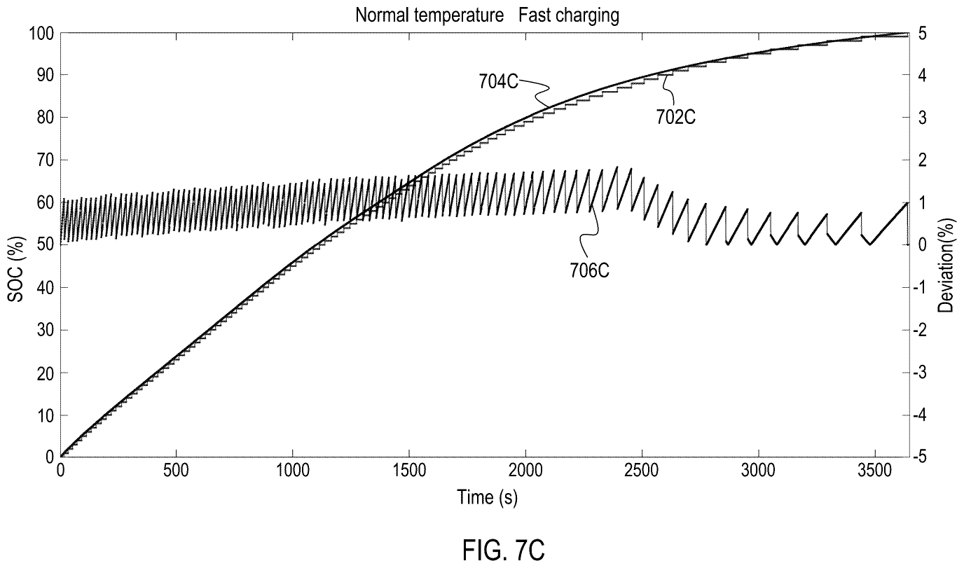

Significant technical effects are achieved by implementing the above-described embodiments according to the present disclosure. The technical effects are explained below with reference to the examples of FIG. 7A to FIG. 8, regarding data obtained during a charging process or during charge-discharge cycles of a battery in example scenarios of implementing the method in the first embodiment with the apparatus in the second embodiment.

Specifically, FIG. 7A illustrates a set of SOC test curves of a lithium battery according to an embodiment of the present disclosure. The battery is subjected to one round of small current charging at 25° C. The lithium battery has a charging capacity of 4900 mAh, a charging cutoff voltage of 4.45V, a charging cutoff current of 200 mA, and a charging current of 0.98 A. The charging process includes resting for one minute, then constant current and constant voltage charging, and then resting for 30 minutes.

FIG. 7B illustrates a set of SOC test curves of a lithium battery according to an embodiment of the present disclosure. The battery is subjected to one round of high-current charging at 25° C. The lithium battery has a charging capacity of 4900 mAh, a charging cutoff voltage of 4.45V, a charging cutoff current of 200 mA, and a charging current of 5.88 A. The charging process includes resting for one minute, then constant current and constant voltage charging, and then resting for 30 minutes.

FIG. 7C illustrates a set of SOC test curves of a lithium battery according to an embodiment of the present disclosure. The battery is subjected to one round of fast charging at 25° C. Specific steps for charging are as follows.

(1) The battery is charged with a constant current of 12.4 A until the battery voltage reaches 4.2V, and then charged with a constant voltage of 4.2V until the battery capacity reaches 1.8 C (at which the current is 8.882 A).

(2) The battery at 1.8 C (at which the current is 8.882 A) is charged with a constant current until the battery voltage reaches 4.3V, and then charged with a constant voltage of 4.3V until the battery capacity reaches 1.5 C (at which the current is 7.35 A).

(3) The battery at 1.5 C (at which the current is 7.35 A) is charged with a constant current until the battery voltage reaches 4.4V, and then charged with a constant voltage of 4.4V until the battery capacity reaches 1.2 C (at which the current is 5.88 A).

(4) The battery at 1.2 C (at which the current is 5.88 A) is charged with a constant current until the battery voltage reaches 4.48V, and then charged with a constant voltage until the battery capacity reaches 0.17 C (at which the current is 0.833 A).

In FIGS. 7A to 7C, the lines 702A, 702B, and 702C each represent an SOC result measured with a calibration cycler, the lines 704A, 704B, and 704C each represent an SOC result determined through the above-described embodiments of the present disclosure, and the lines 706A, 706B, and 706C each represent a deviation between two respective SOC results (e.g., the deviation between lines 702A and 704A, etc.). The horizontal axis represents a charging time, in seconds; the vertical axis corresponding to the measurement/determination result indicates SOC, in percentage; and the vertical axis corresponding to the deviation between the two SOC results indicates a magnitude of the deviation, in percentage.

As can be seen from the examples of low-current charging in FIG. 7A, high-current charging in FIG. 7B, and fast charging in FIG. 7C, throughout the entire charging process, the lithium battery SOC determined through the embodiment in the present disclosure does not jump, and a difference between the SOC and an actual SOC value recorded by the cycler is within 3%. The maximum error for the low-current charging is 1.37%, the maximum error for the high-current charging is 2.04%, and the maximum error for the fast charging is 1.83%.

In addition, the example of FIG. 8 further illustrates a comparison between the SOC determined through the embodiment of the present disclosure and the actual SOC of a lithium battery in 19 charge-discharge cycles. In FIG. 8, the horizontal axis represents the number of charge-discharge cycles, and the vertical axis represents the maximum error between the SOC determined during a charging process and the actual SOC, in percentage. In the example, under a temperature of 25° C., a rated capacity of the lithium battery is 4900 mAh. The charging was carried out in a fast charging mode. The discharging cutoff voltage is 3V and the discharge current is 0.98 A. Each charge-discharge cycle includes constant current discharging, resting for 30 minutes, fast charging, and resting for 30 minutes. The charge-discharge cycle is performed 19 times.

It can be seen that the SOC determined according to the above embodiment does not jump during the entire charging and discharging process. In the 19 charge-discharge cycles, the maximum difference between the SOC determined according to the method in an embodiment of the present disclosure and the actual SOC recorded by the cycler gradually decreased from 7.5% at the beginning to 2.56%, and finally stabilized in the 13th cycle.

In embodiments of the present disclosure, the health value, temperature, current, and FCC database of a battery (e.g., a lithium battery) are utilized to jointly estimate the state of charge SOC of the battery. In this way, the state of charge SOC of the battery can be accurately estimated in an adaptive manner even when there is an error in an initial capacity estimation of the battery (for example, an initial health value is not accurately estimated), so that the battery is prevented from having an artificially high or low SOC due to battery aging or temperature changes.

In summary, with the method and apparatus according to the embodiments of the present disclosure, the actual capacity of a battery (e.g., a lithium battery) is estimated by jointly utilizing the health value, temperature, current, and a two-dimensional lithium battery FCC database of the battery. This allows the battery to be fully charged using high-current charging, low-current charging, or fast charging, and the actual capacity of the battery under high or low temperature conditions can be accurately estimated, so that the battery is prevented from having an artificially high or low SOC due to battery aging or temperature changes. In addition, the SOC is estimated by coulomb integration during the constant current charging stage, and the SOC is approximated based on the relationship between the charging cutoff current and the charging current during the constant voltage charging stage. In this way, overcharging and undercharging of the battery is effectively avoided, the battery life is extended, and user experience is improved.

Basic principles of the present disclosure are described above in conjunction with specific embodiments. However, those skilled in the art can understand that all or any steps or components of the methods and apparatuses of the present disclosure may be implemented in any computing device (including processors, storage media, and the like) or a network of computing devices, in a form of hardware, firmware, software or a combination thereof. Such implementation can be realized by those skilled in the art after reading the description of the present disclosure, by utilizing basic knowledge of circuit design or basic programming skills.

Moreover, a programmable product storing machine-readable instruction code is further provided according to an embodiment of the present disclosure. The instruction codes, when read and executed by a machine, can implement the method according to any of the embodiments of the present disclosure.

Accordingly, a storage medium for carrying the programmable product storing the machine-readable instruction codes is further included in the present disclosure. The storage medium includes, but is not limited to, a floppy disk, an optical disk, a magneto-optical disk, a storage card, a memory stick, and the like. In a case of implementing the embodiments of the present disclosure in software or firmware, a programmable product that includes the software is installed in a computer with a dedicated hardware structure from the storage medium or a network. The computer, when loaded with the various programs, performs various functions.

Components or steps in the method, apparatus and system of the present disclosure may be decomposed and/or recombined. Such decomposition and/or recombination should be considered as equivalents of the present disclosure. Furthermore, steps for executing the above processes may naturally be executed in a chronological order as described, but do not necessarily need to be executed in the chronological order. Certain steps may be performed in parallel with or independently of each other.

Finally, the terms “include,” “comprise” or any other variants thereof are intended to be non-exclusive. Therefore, a process, method, article, or device including a series of elements or components includes not only those elements/components but also includes, or may include, other elements/components that are not enumerated, or further includes elements/components inherent to the process, method, article, or device. In addition, unless expressly stated otherwise, the statement “comprising (including) a(n) . . . ” does not exclude the existence or presence of other identical or equivalent elements in the process, method, article or device.

The following configurations are provided in the present disclosure.

1. A method for determining a state of charge of a battery, the method comprising: determining a corrected full charge capacity (FCC) of the battery based on an FCC correction parameter and an initial estimated FCC corresponding to an initial battery parameter of the battery; and determining a present state of charge (SOC) of the battery based at least in part on the corrected FCC, wherein the initial estimated FCC is determined by querying an FCC database based on the initial battery parameter, the FCC database storing at least a first plurality of battery parameters and respective FCCs, and wherein the FCC correction parameter is determined based on a deviation between an estimated SOC and an actual SOC of the battery, and wherein the estimated SOC is determined by querying an SOC database based on a second plurality of battery parameters including the initial battery parameter, the SOC database storing the second plurality of battery parameters and respective SOC values.

2. The method according to configuration 1, wherein the initial battery parameter comprises at least a current and a temperature.

3. The method according to any of configurations 1 and 2, wherein the querying an FCC database based on the initial battery parameter comprises: querying for relevant data items in the FCC database based on the initial battery parameter; and determining the initial estimated FCC according to FCCs in the relevant data items and also based on differences between battery parameters in the relevant data items and the initial battery parameters.

4. The method according to any of configurations 1-3, wherein the querying an SOC database based on the combination of battery parameter comprises: querying the SOC database based on a first equivalent voltage, an initial current, and an initial temperature of the battery, to obtain a first SOC value from the SOC database; querying the SOC database based on a second equivalent voltage, the initial current, and the initial temperature of the battery, to obtain a second SOC value from the SOC database; and determining a difference between the first SOC value and the second SOC value, wherein the difference is the estimated SOC, wherein the first equivalent voltage is a sum of an idle voltage and a charging impedance voltage of the battery, and the second equivalent voltage is a sum of a charging cutoff voltage and a charging impedance voltage of the battery.

5. The method according to any of configurations 1-4, wherein the determining a present SOC of the battery based at least in part on the corrected FCC further comprises: determining a charging mode of the battery based on present values of the second plurality of battery parameters; and determining the present SOC depending on the determined charging mode.

6. The method according to any of configurations 1-5, wherein the determined charging mode is a constant current charging mode, in which case the present SOC is determined based on a present charge level of the battery and the corrected FCC.

7. The method according to any of configurations 1-5, wherein the determined charging mode is a constant voltage charging mode, in which case the present SOC is determined based on a relationship between a present charging current of the battery and a present reference current, wherein the present reference current is determined based at least on a previous SOC, a previous charging current and a charging cutoff current of the battery.

8. The method according to any of configurations 1-4, 6, and 7, wherein the determining the present SOC based on the relationship between the present charging current and the present reference current comprises: determining the present SOC as a sum of a previous SOC and a predetermined SOC increment if a difference between the present charging current and the present reference current is zero.

9. The method according to any of configurations 1-4 and 6-8, wherein the difference is determined based on a sum of i) a first difference between the present charging current and the previous charging current and ii) a second difference between a previous charging current and the charging cutoff current. The previous charging current is adjusted based on the previous SOC and a predetermined adjustment factor.

10. The method according to any of configurations 1-9, further comprising: when a preset update condition is met, updating relevant data items in the FCC database using an FCC error, wherein the FCC error is a calculated deviation between a present estimated FCC and an actual FCC, the present estimated FCC being determined by querying the FCC database based on statistical battery parameters.

11. The method according to any of configurations 1-10, wherein the relevant data items to be updated in the FCC database are determined based at least on the statistical battery parameters.

12. The method according to any of configurations 1-11, wherein the updating the relevant data items in the FCC database comprises: calculating update weights for the relevant data items based on differences between battery parameters in the relevant data items and the statistical battery parameters; and updating FCCs corresponding to the relevant data items in the FCC database based on the FCC error and the update weights for the relevant data items.

13. The method according to any of configurations 1-12, wherein the update weights for the relevant data items are calculated based on differences for the statistical battery parameters.

14. The method according to any of configurations 1-13, wherein the statistical battery parameters comprise at least a maximum current and an average temperature.

15. The method according to any of configurations 1-14, wherein the actual FCC is a sum of i) a cumulative charging capacity during a charging process for the battery, ii) a remaining capacity before charging, and iii) a capacity correction value, wherein the capacity correction value is obtained based on a deviation between an actual SOC at charging cutoff and an estimated SOC determined by querying the SOC database based on a plurality of battery parameters including a charging cutoff current.

16. An apparatus for determining a state of charge of a battery, the apparatus comprising: a memory and a processing circuit. The processing circuit is configured to: determine a corrected full charge capacity (FCC) of the battery based on an FCC correction parameter and an initial estimated FCC corresponding to an initial battery parameter of the battery; and determine a present state of charge (SOC) of the battery based at least in part on the corrected FCC, wherein the initial estimated FCC is determined by querying an FCC database based on the initial battery parameters, the FCC database storing at least a first plurality of battery parameters and respective FCCs, and wherein the FCC correction parameter is determined based on a deviation between an estimated SOC and an actual SOC of the battery, and wherein the estimated SOC is determined by querying an SOC database based on a second plurality of battery parameters including the initial battery parameters, the SOC database storing the second plurality of battery parameters and respective SOC values.

17. The apparatus according to configuration 16, wherein the initial battery parameters comprise at least a current and a temperature.

18. The apparatus according to any of configurations 16 and 17, wherein the processing circuit is further configured to: query for relevant data items in the FCC database based on the initial battery parameters; and determine the initial estimated FCC according to FCCs in the relevant data items and also based on differences between battery parameters in the relevant data items and the initial battery parameters.

19. The apparatus according to any of configurations 16-18, wherein the processing circuit is further configured to: query the SOC database based on a first equivalent voltage, an initial current, and an initial temperature of the battery, to obtain a first SOC value from the SOC database; query the SOC database based on a second equivalent voltage, the initial current, and the initial temperature of the battery, to obtain a second SOC value from the SOC database; and determine a difference between the first SOC value and the second SOC value, wherein the difference is the estimated SOC, wherein the first equivalent voltage is a sum of an idle voltage and a charging impedance voltage of the battery, and the second equivalent voltage is a sum of a charging cutoff voltage and a charging impedance voltage of the battery.

20. The apparatus according to any of configurations 16-19, wherein the processing circuit is further configured to: determine a charging mode of the battery based on present values of the second plurality of battery parameter; and determine the present SOC depending on the determined charging mode.

21. The apparatus according to any of configurations 16-20, wherein the determined charging mode is a constant current charging mode, in which case the present SOC is determined based on a present charge level of the battery and the corrected FCC.

22. The apparatus according to any of configurations 16-20, wherein the determined charging mode is a constant voltage charging mode, in which case the present SOC is determined based on a relationship between a present charging current of the battery and a present reference current, wherein the present reference current is determined based at least on a previous SOC, a previous charging current and a charging cutoff current of the battery.

23. The apparatus according to any of configurations 16-20 and 22, wherein the processing circuit is further configured to: determine the present SOC as a sum of a previous SOC and a predetermined SOC increment if a difference between the present charging current and the present reference current is zero.

24. The apparatus according to any of configurations 16-20, 22, and 23, wherein the difference is determined based on a sum of i) a first difference between the present charging current and the previous charging current and ii) a second difference between the previous charging current and the charging cutoff current. The previous charging current is adjusted based on the previous SOC and a predetermined adjustment factor.

25. The apparatus according to any of configurations 16-24, wherein the processing circuit is further configured to: when a preset update condition is met, update relevant data items in the FCC database using an FCC error, wherein the FCC error is a calculated deviation between a present estimated FCC and an actual FCC, the present estimated FCC determined by querying the FCC database based on statistical battery parameters.

26. The apparatus according to any of configurations 16-25, wherein the processing circuit is further configured to: determine the relevant data items to be updated in the FCC database based at least on the statistical battery parameters.

27. The apparatus according to any of configurations 16-26, wherein the processing circuit is further configured to: calculate update weights for the relevant data items based on differences between battery parameters in the relevant data items and the statistical battery parameters; and update FCCs corresponding to the relevant data items in the FCC database based on the FCC error and the update weights for the relevant data items.

28. The apparatus according to any of configurations 16-27, wherein the processing circuit is further configured to: calculate the update weights for the relevant data items based on differences for the statistical battery parameters.

29. The apparatus according to any of configurations 16-28, wherein the statistical battery parameters comprise at least a maximum current and an average temperature.

30. The apparatus according to any of configurations 16-29, wherein the actual FCC is a sum of i) a cumulative charging capacity during a charging process for the battery, ii) a remaining capacity before charging, and iii) a capacity correction value, wherein the capacity correction value is determined based on a deviation between an actual SOC at charging cutoff and an estimated SOC obtained by querying the SOC database based on the battery parameters including a charging cutoff current.

31. A machine-readable program product recording a machine-readable program, wherein the machine-readable program, when executed by a processor, implements the method for determining a state of charge of a battery according to any of configurations 1 to 15.

Although the embodiments of the present disclosure are described in detail above with reference to the accompanying drawings, the embodiments are only for illustrating the present disclosure and do not constitute a limitation of the present disclosure. For those skilled in the art, various modifications and changes can be made to the embodiments without departing from the spirit and scope of the present disclosure. Therefore, the scope of the present disclosure is limited only by the appended claims and equivalents thereof.

What is claimed is:

1. A computer-implemented method for determining a state of charge of a battery, the method comprising:
determining a corrected full charge capacity (FCC) of the battery based on an FCC correction parameter and an initial estimated FCC corresponding to initial battery parameters of the battery; and
determining a present state of charge (SOC) of the battery based at least in part on the corrected FCC,
wherein the initial estimated FCC is determined by querying an FCC database based on the initial battery parameters, the FCC database storing at least a first plurality of battery parameters and respective FCCs, and
wherein the FCC correction parameter is determined based on a deviation between an estimated SOC and an actual SOC of the battery, and wherein the estimated SOC is determined by querying an SOC database based on a second plurality of battery parameters including the initial battery parameters, the SOC database storing the second plurality of battery parameters and respective SOC values.

2. The computer-implemented method according to claim 1, wherein the initial battery parameters comprise at least a current and a temperature.

3. The computer-implemented method according to claim 2, wherein said querying further comprises:
querying the SOC database based on a first equivalent voltage, an initial current, and an initial temperature of the battery, to obtain a first SOC value from the SOC database;
querying the SOC database based on a second equivalent voltage, the initial current, and the initial temperature of the battery, to obtain a second SOC value from the SOC database; and
determining a difference between the first SOC value and the second SOC value, wherein the difference is the estimated SOC,
wherein the first equivalent voltage is a sum of an idle voltage and a charging impedance voltage of the battery, and the second equivalent voltage is a sum of a charging cutoff voltage and a charging impedance voltage of the battery.

4. The computer-implemented method according to claim 1, wherein said querying further comprises:
querying for relevant data items in the FCC database based on the initial battery parameters; and
determining the initial estimated FCC according to FCCs in the relevant data items and also based on differences between battery parameters in the relevant data items and the initial battery parameters.

5. The computer-implemented method according to claim 1, wherein said determining a present SOC of the battery based at least in part on the corrected FCC further comprises:
determining a charging mode of the battery based on present values of the second plurality of battery parameters; and
determining the present SOC depending on the determined charging mode.

6. The computer-implemented method according to claim 5, wherein the determined charging mode is a constant current charging mode, in which case the present SOC is determined based on a present charge level of the battery and the corrected FCC.

7. The computer-implemented method according to claim 5, wherein the determined charging mode is a constant voltage charging mode, in which case the present SOC is determined based on a relationship between a present charging current of the battery and a present reference current, wherein the present reference current is determined based at least on a previous SOC, a previous charging current, and a charging cutoff current of the battery.

8. The computer-implemented method according to claim 7, wherein said determining the present SOC based on the relationship between the present charging current and the present reference current comprises:
determining the present SOC as a sum of a previous SOC and a predetermined SOC increment if a difference between the present charging current and the present reference current is zero.

9. The computer-implemented method according to claim 8, wherein the difference is determined based on a sum of i) a first difference between the present charging current and the previous charging current and ii) a second difference between the previous charging current and the charging cutoff current, wherein the previous charging current is adjusted based on the previous SOC and a predetermined adjustment factor.

10. The computer-implemented method according to claim 1, further comprising:
when a preset update condition is met, updating relevant data items in the FCC database using an FCC error, wherein the FCC error is a calculated deviation between a present estimated FCC and an actual FCC, the present estimated FCC determined by querying the FCC database based on statistical battery parameters.

11. The computer-implemented method according to claim 10, wherein the relevant data items to be updated in the FCC database are determined based at least on the statistical battery parameters.

12. The computer-implemented method according to claim 11, wherein said updating comprises:
calculating update weights for the relevant data items based on differences between battery parameters in the relevant data items and the statistical battery parameters; and
updating the FCCs corresponding to the relevant data items in the FCC database based on the FCC error and the update weights for the relevant data items.

13. The computer-implemented method according to claim 12, wherein the update weights for the relevant data items are calculated based on differences for the statistical battery parameters.

14. The computer-implemented method according to claim 12, wherein the statistical battery parameters comprise at least a maximum current and an average temperature.

15. The computer-implemented method according to claim 10, wherein the actual FCC is a sum of i) a cumulative charging capacity during a charging process for the battery, ii) a remaining capacity before charging, and iii) a capacity correction value, wherein the capacity correction value is obtained based on a deviation between an actual SOC at charging cutoff and an estimated SOC determined by querying the SOC database based on a plurality of the battery parameters including a charging cutoff current.

16. An apparatus for determining a state of charge of a battery, the apparatus comprising
a memory; and
a processing circuit coupled to the memory and configured to:
determine a corrected full charge capacity (FCC) of the battery based on an FCC correction parameter and an initial estimated FCC corresponding to initial battery parameters of the battery; and
determine a present state of charge (SOC) of the battery based at least in part on the corrected FCC,
wherein the initial estimated FCC is determined by querying an FCC database based on the initial battery parameters, the FCC database storing at least a first plurality of battery parameters and respective FCCs, and
wherein the FCC correction parameter is determined based on a deviation between an estimated SOC and an actual SOC of the battery, and wherein the estimated SOC is determined by querying an SOC database based on a second plurality of battery parameters including the initial battery parameters, the SOC database storing the second plurality of battery parameters and respective SOC values.

17. The apparatus according to claim 16, wherein the processing circuit is further configured to:
query for relevant data items in the FCC database based on the initial battery parameters; and
determine the initial estimated FCC according to FCCs in the relevant data items and also based on differences between battery parameters in the relevant data items and the initial battery parameters.

18. The apparatus according to claim 16, wherein the processing circuit is further configured to:
determine a charging mode of the battery based on present values of the second plurality of battery parameters; and
determine the present SOC depending on the determined charging mode.

19. The apparatus according to claim 18, wherein the processing circuit is further configured to:
if the determined charging mode is a constant voltage charging mode, determine the present SOC based on a relationship between a present charging current of the battery and a present reference current, wherein the present reference current is determined based at least on a previous SOC, a previous charging current and a charging cutoff current of the battery.
